(19) United States
(12) Patent Application Publication
(10) Pub. No.: US 2004/0231911 A1
(43) Pub. Date: Nov. 25, 2004

(54) Outdoor loudspeaker with passive radiator

(76) Inventors: Andrew C. Welker, Courtice (CA); John Tchilinguirian, Bowmanville (CA)

Correspondence Address: BERESKIN AND PARR, SCOTIA PLAZA, 40 KING STREET WEST-SUITE 4000 BOX 401, TORONTO, ON, M5H 3Y2, CA

(21) Appl. No.: 10/816,842

(22) Filed: Apr. 5, 2004

Related U.S. Application Data
(60) Provisional application No. 60/459,962, filed on Apr. 4, 2003.

(51) Int. Cl. H05K 5/00; H04R 7/00; G10K 13/00

(52) U.S. Cl. 181/165; 181/163; 181/144

(57) ABSTRACT

A loudspeaker with a sealed enclosure having an active driver and a passive radiator mounted thereon is disclosed. The passive radiator is mounted essentially centrally in a passive radiator aperture and is held in place by a suspension which permits it to move in only a substantially linear direction. The enclosure and diaphragm are formed together in an injection molding process and the suspension is then co-molded between the diaphragm and enclosure. The loudspeaker has a mounting bracket that permits it be locked in a selected rotated position relative to the bracket. The active driver may be provided with a reflector to produce an omni-polar, or omni-directional, sound pattern.

### FIELD OF THE INVENTION

This invention relates to loudspeakers intended for outdoor use. More particularly it relates to loudspeakers with a sealed enclosure and one or more integrated passive radiation elements.

### BACKGROUND OF THE INVENTION

Loudspeakers for outdoor use are preferably designed to survive the elements and also to provide a high quality sound reproduction.

When a loudspeaker is used outdoor, numerous challenges not faced in indoor use arise. The loudspeaker may be subject to the penetration by moisture, insects and debris. To counter these and other problems, it is desirable to provide a loudspeaker with a sealed enclosure that is air-tight, or substantially air-tight. Preferably, the enclosure should be at least water-tight or moisture-tight to prevent penetration of the enclosure by moisture and by other objects.

A significant disadvantage of sealing the enclosure of a loudspeaker is that the enclosed volume tends to dampen the low frequency response of active drivers mounted on the enclosure. Movement of the driver's diaphragm causes the enclosed volume to be compressed and expanded. The enclosed volume applies an opposing force to the driver's diaphragm as it moves, reducing its movement. The effect of this opposing force is greatest on the driver's low frequency response, since the driver's diaphragm will typically have a longer motion when reproducing low frequency sounds.

Accordingly, it is desirable to provide a speaker for outdoor use with a sealed enclosure that does not substantially reduce the low frequency response of an active driver installed on the enclosure.

### SUMMARY OF THE INVENTION

The present invention provides an improved loudspeaker intended primarily for outdoor use. The loudspeaker is also suitable for indoor use.

The loudspeaker has a sealed enclosure with at least one active driver mounted on it. The active driver has an active diaphragm that is supported by a surround (or suspension) that permits the active diaphragm to move into and out of the volume of the enclosure. The active driver is installed in an active driver aperture formed in the surface of the enclosure. The enclosure also has a passive sound radiator, which has a passive diaphragm supported by a suspension (or surround). The passive diaphragm is preferably positioned centrally in a passive radiator aperture formed in the enclosure.

Preferably the active drive and its surround (and other parts of the active driver that are exposed on the outside of the enclosure) provide a continuous seal across the active driver aperture. Similarly, the passive diaphragm and its suspension provide a continuous seal across the passive radiator aperture. The seals are preferably airtight or substantially air tight seal. Alternatively, the seals are at least water-tight or moisture-tight. A quality of the seal required may be chosen depending on the degree of protection required or desired for a particular loudspeaker according to the present invention.

A volume of a loudspeaker according to the present invention is thus protected from the elements, insects and debris.

The passive diaphragm moves in response to motion of the active diaphragm, thereby reducing any attenuating effects that would result from alternate compression and expansion of the gases filling the sealed enclosure.

The passive radiator may be tuned, by selecting the characteristics of the passive diaphragm and suspension, including their mass and dimensions. By tuning the passive radiator to a frequency below the low frequency cutoff (for example, the 3 dB cutoff) of an identical loudspeaker without a passive radiator, the low frequency response of the loudspeaker can be extended

The present invention thus also provides an improved sound response by extending the low frequency response of a loudspeaker made according to the present invention compared to the low frequency response of an otherwise identical loudspeaker made without a passive radiator.

A loudspeaker according to the present invention may have multiple drivers, operating in the same or different frequency ranges mounted on the enclosure, and may have multiple passive radiators mounted on the enclosure.

The present invention also provides a method for manufacturing a loudspeaker with the passive diaphragm centrally positioned in the passive radiator aperture. The enclosure (or at least the part of the enclosure in which the passive radiator aperture is formed) is injection molded at the same time as the passive diaphragm. The suspension for the passive diaphragm is then co-molded with the enclosure and the passive diaphragm, providing the desired seal and ensuring the passive diaphragm is positioned centrally in the passive radiator aperture. This allows the passive diaphragm to move linearly and improves the quality of the sound produced by the passive diaphragm.

The present invention also provides a bracket for mounting a loudspeaker with a sealed enclosure. The exterior of the loudspeaker's enclosure has at least one mounting channel with an “L” shaped cross section. A bracket has a mounting plate and a locking plate. The mounting plate may be mounted on a support surface using screws, nuts and bolts or other fasteners of adhesives. The mounting plate has at least one support arm that fits into an insertion channel of the mounting channels. A locking plate fits slideably in the mounting plate. The locking plate has at least one locking arm which has an extension member and a locking member arranged in an “L” shape complementary to the cross section of the mounting channel. The locking plate may be moved within the mounting plate between an unlocked position and a locked position using a locking screw. The loudspeaker is mounted on the bracket by first setting the locking plate to its unlocked position in which the locking arm extends through an aperture in the mounting plate and is aligned with the support arms of the mounting plate. The support arms and locking arms are then positioned in the mounting channel. The locking screw is used to move the locking members in the locking channel of the mounting channel, locking the loudspeaker on the bracket. The bracket may be mounted at any angle on the external support surface, allowing the loudspeaker to be mounted at any angle.

The exterior of the loudspeaker's enclosure may also be provided with two or more detents that align with one or more shoulders formed on the mounting bracket when the loudspeaker is positioned on the mounting bracket. The shoulders may be selectably positioned with a corresponding number of detents to prevent the bracket's support arms and locking arms from sliding in the mounting channels. This allows the loudspeaker to be positioned in a selected rotated position relative to the mounting bracket.

The active driver of the loudspeaker may also be provided with a reflector for shaping the sound field produced by the driver. The driver and reflector may be positioned to provided an omni-polar, omni-directional, sound field around the speaker. In addition, a high frequency driver may be provided and may be provided with its own reflector.

### BRIEF DESCRIPTION OF THE DRAWINGS

A preferred embodiment of the present invention will now be described in detail with reference to the drawings, in which:

FIG. 1 is a front isometric of a loudspeaker made in accordance with the present invention;

FIG. 2 is a rear isometric view of the loudspeaker;

FIG. 3 is a side sectional view of the loudspeaker;

FIG. 4 is a rear sectional isometric view of the loudspeaker;

FIG. 5 illustrates a pair of plates that are part of a mold used to form a cover, a passive diaphragm and a suspension of the loudspeaker;

FIG. 6 illustrates the mold configured to form the cover and passive diaphragm;

FIG. 7 illustrates the mold configured to form the passive diaphragm;

FIG. 8 is a front isometric view of a mounting bracket used to mount the loudspeaker of FIG. 1 on an external support, with mounting bracket in an unlocked state;

FIG. 9 is a front isometric view of the mounting bracket in an locked state;

FIG. 10 is an exploded view of the mounting bracket; and

FIG. 11 is a rear isometric view of the mounting bracket.

### DETAILED DESCRIPTION OF EXEMPLARY EMBODIMENTS

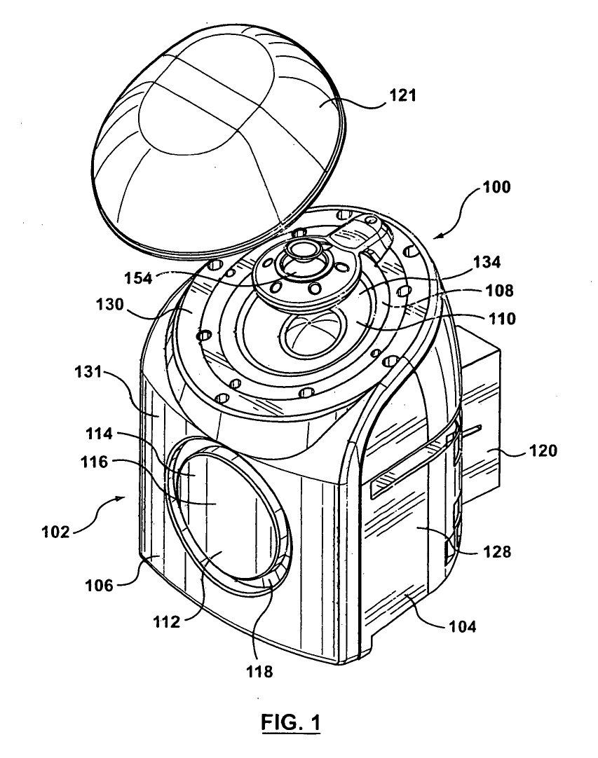

Reference is first made to FIGS. 1 to 4, which illustrate an exemplary loudspeaker 100 according to the present invention. Loudspeaker 100 has an enclosure 102 assembled from a base 104 and a cover 106. Enclosure 102 has an active driver aperture 108 in which an active driver 110 is mounted. Enclosure 102 also has a passive radiator aperture 112 in which a passive sound radiator 114 is mounted. Passive sound radiator 114 has a passive diaphragm 116 and a suspension 118. A mounting bracket 120 is shown attached to loudspeaker 100.

Base 104 provides a bottom 126, sides 127, 128 and a back 129 for enclosure 102. Cover 106 provides a top 130 and a front 131 for enclosure 102. The specific structure of loudspeaker 100 is only exemplary and other configurations with multiple covers and different shapes may be used. Cover 106 is mounted to base 104 using screws 132. Cover 106 is preferably mounted to base 104 with an airtight or substantially air tight seal. Preferably, the seal between cover 106 and base 104 is at least water-tight or moisture-tight. A gasket (not shown) made or rubber or another appropriate material may be used to provide the desired seal between cover 106 and base 104.

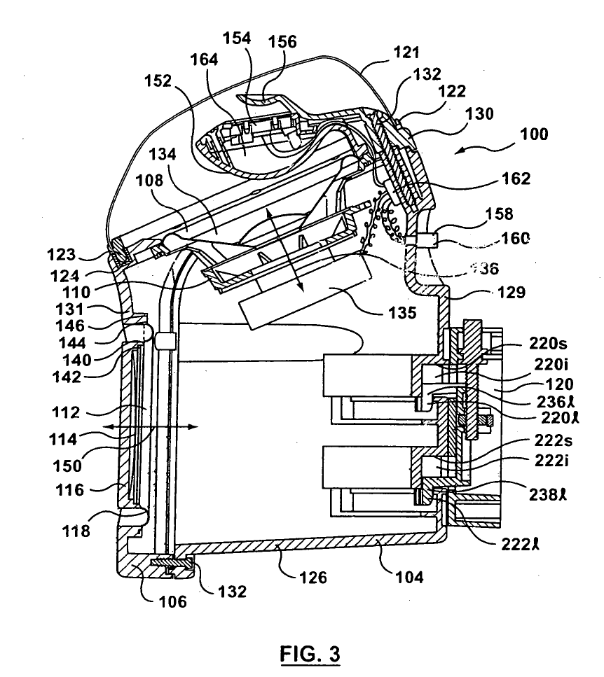

Active driver aperture 108 is formed on the top 130 of enclosure 102. Active driver 110 is mounted in active driver aperture 108 with a seal that is preferably air-tight or substantially air-tight, and is at least water-tight or moisture-tight. Active driver 110 preferably has an active diaphragm 134 that travels in a generally linear back-and-forth motion in active diaphragm movement direction 136 (FIG. 3). Active diaphragm 134 is preferably made from a weatherproof or weather-resistant material, such as a treated paper, plastic, metal or a composite material. Active diaphragm 134 is support by a flexible surround 135, which also preferably made of a weatherproof or weather-resistant material such as rubber or plastic. Active diaphragm 134 and suspension 135 are mounted so that they form a continuous seal across active driver aperture 108, ensuring that the volume within enclosure 102 remains sealed. Active driver 120 has a coil 135 which controls the movement of active diaphragm 134. Coil 135 is shown only if FIG. 3 and is omitted in the other Figures for clarity.

Driver 120 of loudspeaker 100 is provided with a sound reflector 152 that is used to reflect the sound produced by driver 120 in an omni-polar sound dispersion pattern. Loudspeaker 100 also has a high-frequency driver 154 that has a corresponding sound reflector 156. An electrical signal embodying an audio signal is received at terminals 158 and 160 (shown only in FIG. 3). The signal is divided into different frequency components by cross-over 162 (shown only in FIG. 3) and suitable frequency components are applied to drivers 120 and 154, which produce sound waves in response. The structure and positioning of drivers 120 and 154, and their corresponding sound reflectors 152 and 156 is described in co-pending U.S. application Ser. No. 10/378,087, the description of which is attached hereto as Appendix A, and which is incorporated herein by this reference. This structure and positioning are used in the OMNI™ series of loudspeakers manufactured and sold by Audio Products International Corporation.

High-frequency driver 154 is mounted in a cavity 164 in reflector 152. The volume of cavity 164 may be continuous with the volume of enclosure 102, or it may be sealed from the volume of enclosure 102 using a gasket or seal that isolates cavity 164 from the volume of enclosure 102. In either case, it is desirable that high-frequency driver 154 is mounted in cavity 164 with an air-tight, substantially air-tight, water-tight or at least moisture-tight seal, as described above in relation to the seal between cover 106 and base 104. Loudspeaker 100 has a seal 105 that separates cavity 164 from the volume of enclosure 102.

The omni-polar sound dispersion pattern of driver 120 is not a limiting feature of the present invention. Loudspeaker 100 could alternatively be constructed without reflector 152 and without driver 154 or reflector 156. Loudspeaker 100 merely requires that an active driver 120 be mounted to a sealed enclosure 102. Active driver 120 could be mounted on the front 131 or any other part of enclosure 102.

Loudspeaker 100 has a cap 121 which fits over top 130 of loudspeaker 100. FIG. 1 illustrates the cap 121 lifted away from top 130. Cap 121 may be installed by any suitable means, such as friction fitting, screw, clips of other mounting or fastening means. In loudspeaker 100, cap 121 has a mounting ring 122, which may be made of rubber, plastic or other material. Ring 122 has a plurality of plugs 123 which align with and frictionally engage corresponding detents 124 in top 130. Cap 121 is preferably acoustically transparent so that it does not affect sound generated by loudspeaker 100. Preferably, mounting ring 122 provides seal between cap 121 and top 130 in order to keep debris, insects, and any substantial amount of moisture or water away from driver 110. However, cap 121 is not part of the enclosure of loudspeaker 100, and it is not necessary to the present invention that it provides such a seal with top 130.

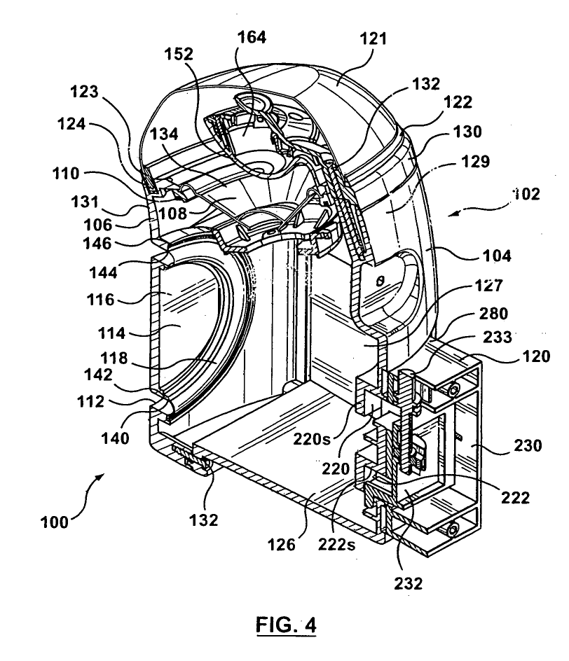

Reference is made to FIGS. 3 and 4. Suspension 116 has an inner edge 140 that is mounted adjacent the perimeter 142 of passive diaphragm 116 and an outer edge that 144 is mounted adjacent the edge 146 of passive radiator aperture 112.

As noted above, enclosure 102 is preferably sealed air-tight or substantially air-tight. Preferably, enclosure 102 is at least water-tight or moisture-tight. Accordingly, suspension 116 is sealed continuously at its inner and outer edges to passive diaphragm 116 and enclosure 102 to provide the desired degree of sealing of enclosure 102.

Suspension 116 is formed concentrically around passive diaphragm 116 and allows passive diaphragm 116 to move linearly in a back and forth motion in a passive diaphragm movement direction 150 (FIG. 3). Passive diaphragm movement direction 150 is generally normal to the surface of passive diaphragm 116. Passive diaphram has a slightly curved surface matching the generally curved surface of the front 131 of enclosure 102. Passive diaphragm movement direction is essentially normal to the center of passive diaphragm 116, such that passive diaphragm 116 does not substantially rock from edge to edge as it moves and such that all points on diaphragm 116 as displaced linearly by essentially the same distance and any particular time.

Enclosure 102 may be formed of various materials including ABS, polypropylene, polyethylene, acrylic, polystyrene, lexan, thermoset materials, thermoplastic rubbers and other materials which will be within the knowledge of a skilled person. Base 104 and cover 106 may be made using an injection molding process.

Passive diaphragm 116 is positioned essentially or substantially centrally (i.e. concentrically) within passive radiator aperture 112. This helps to ensure that passive diaphragm 116 moves linearly in direction 150. The present invention provides a method for manufacturing loudspeaker 100 so that passive diaphragm 116 is concentrically positioned within passive radiator passive radiator aperture 112. The passive diaphragm may be circular or essentially circular, as in loudspeaker 100. Alternatively, the passive diaphragm may have an elliptical, oval, square, rectangular or other shape. Preferably, the passive radiator aperture has a corresponding shape and the passive radiator suspension holds the passive diaphragm in an essentially or substantially concentric or central position within the passive radiator aperture.

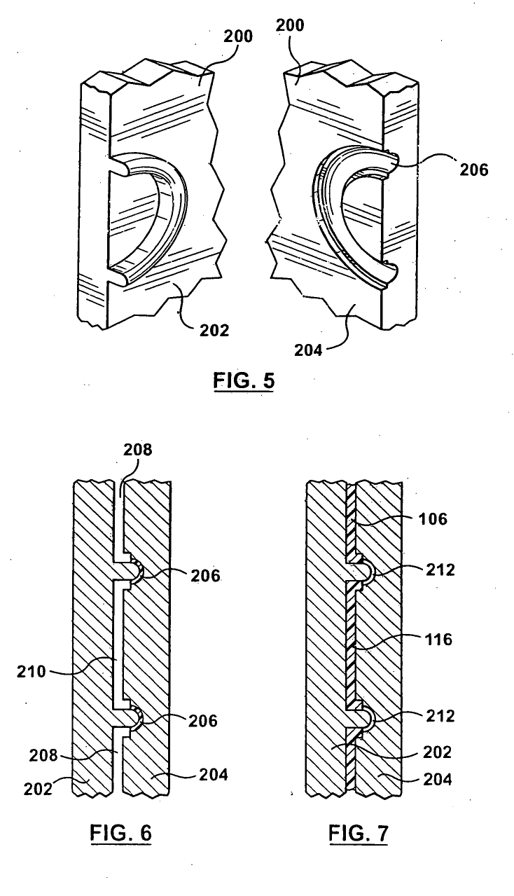

Reference is made to FIG. 5, which illustrates part of an injection mold 200 that may be used to form cover 106 and passive radiator 114 in cross-section. Mold 200 has two plates 202 and 204 and an insert 206 which may be optionally installed in plate 204. Injection gates and other components of mold 200 are not shown. A skilled person will be familiar with such aspects of injection molds and injection molding procedures.

Reference is made to FIG. 6. When plates 202 and 204 are assembled with insert 206 installed, they define cavities 208 and 210. Cavity 208 is used to mold cover 106 and cavity 210 is used to mold passive diaphragm 116.

Reference is made to FIG. 7. When plates 202 and 204 are assembled without insert 206 installed, they define an additional cavity 212, which is continuous with cavities 208 and 210. Cavity 212 is used to mold suspension 118.

Cover 106 and passive radiator 114 are formed as follows. Plates 202 and 204 are assembled with insert 206 installed and resin is injected into cavities 208 and 210. The same resin may be used in both cavities, or alternatively different resin may be used if it is desired to form cover 106 and passive diaphragm 116 from different materials. The injected resin eventually solidifies to form cover 106 and passive diaphragm 116. When the injected resin has sufficiently solidified, plate 204 is removed. Cover 106 and passive diaphragm 116 remain in position on plate 202. Insert 206 is removed from plate 204 and plate 204 is replaced on plate 202. Suspension 118 is then co-molded with cover 106 and passive diaphragm 116 by injecting a resin into cavity 212 to form suspension 118. Typically, the resin used to form suspension 118 will be a rubber or other material that is flexible when suspension 118 has solidified. When suspension 118, cover 106 and passive diaphragm 116 are sufficiently solidified, they are removed from mold 200.

In one embodiment of the present invention, suspension 118 is co-molded with cover 106 and passive diaphragm 116 before cover 106 and passive diaphragm 116 have fully solidified. The resin used to form suspension 118 interacts with the still unsolidified resin of the cover 106 and passive diaphragm 116, creating a seal between them. Depending on the resin used to form cover 106, passive diaphragm 116 and suspension 118, a molecular bond may be formed between cover 106 and suspension 118 and between passive diaphragm 116 and suspension 118.

Alternatively, suspension 118 may be co-molded with cover 106 and passive diaphragm 116 after cover 106 and passive diaphragm 116 have solidified.

Mold 200 may be configured differently within the scope of the present invention. For example, mold 200 may comprise three plates. One plate may be identical to plate 202. The second plate may be identical to plate 204 with insert 206 installed. The third plate may be identical to plate 204 with insert 206 removed. The first and second plates may be assembled together to form cover 106 and passive diaphragm 116. The first and third plates may then be assembled together to form suspension 118. Alternatively, mold 200 may comprise two plates essentially identical to plates 202 and 204. One or both of the plates may be provided with controllable blocking elements. The blocking elements may be positioned to prevent resin from entering cavity 212 while cover 106 and passive diaphragm 116 are being formed and may then be moved (into a recess in one or both plates) to form suspension 118. The block elements may be externally controllable, allowing cover 106, passive diaphragm 116 and suspension 118 to be formed without separating the plates.

Loudspeaker 100 has an enclosed volume that is sealed from the exterior of loudspeaker 100. Base 104, cover 106, active driver 106 and passive radiator 116 provide a continuous sealed enclosure 102. If driver 106 is provided with a reflector 152 and the cavity 164 within the reflector 152 is continuous with the volume of enclosure 102, then reflector 152 and high-frequency driver 154 also assist in providing a sealed volume within enclosure 102. In volume of loudspeaker 100 is thus protected from the elements, such as moisture, insects and debris, when loudspeaker 100 is used outdoors.

Passive radiator 114 moves in direction 150 in response to the motion of active diaphragm 134 of active driver 106, substantially reducing the low frequency attenuation effects of sealing enclosure 102. Passive radiator 114 may be tuned to a selected frequency so that the low frequency response of loudspeaker 100 is extended compared to the low frequency response of an identical speaker without passive radiator 106. A skilled person will be able to design the passive diaphragm 116 and suspension 118 so that passive radiator is tuned to the selected frequency. Typically, the selected frequency will be slightly below the cutoff frequency for an identical loudspeaker without passive radiator 114.

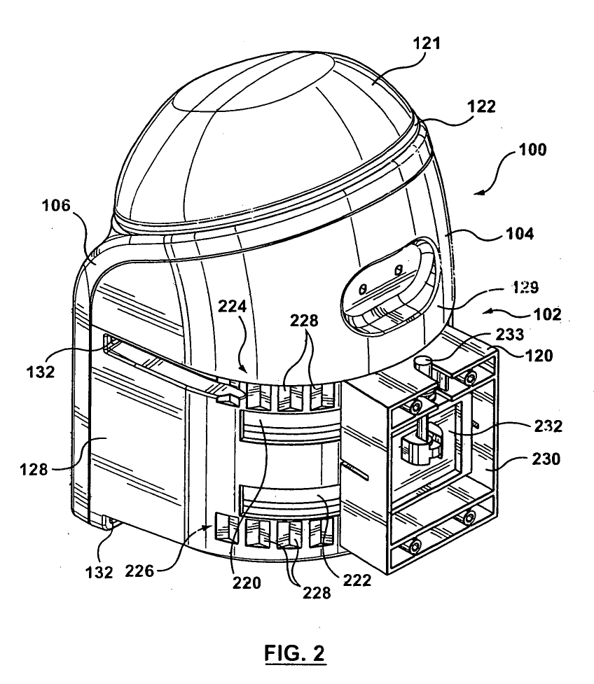

Reference is next made to FIGS. 2, 3 and 4 which illustrate the back 129 of loudspeaker 100 with mounting bracket 120 installed on it. Two mounting channels 220, 222 are formed along the surface of back 129. Mounting channel 220 has an “L” shaped cross section (see FIG. 3) formed by an insertion channel 220i and a locking channel 2201. Insertion channel 220i has a support surface 220s. Similarly, mounting channel 222 has an insertion channel 222i and a locking channel 2221. Insertion channel 222i has a support surface 222s. Loudspeaker 100 has also has two rows 224, 226 of detents 228 arranged parallel to mounting channels 220, 222.

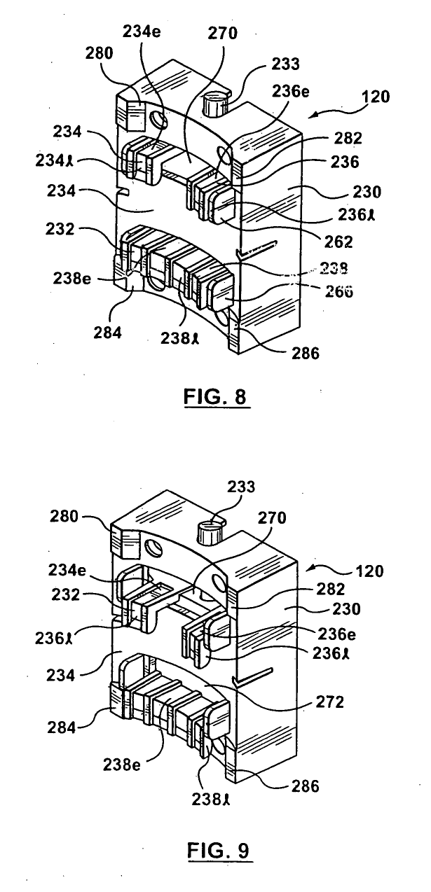

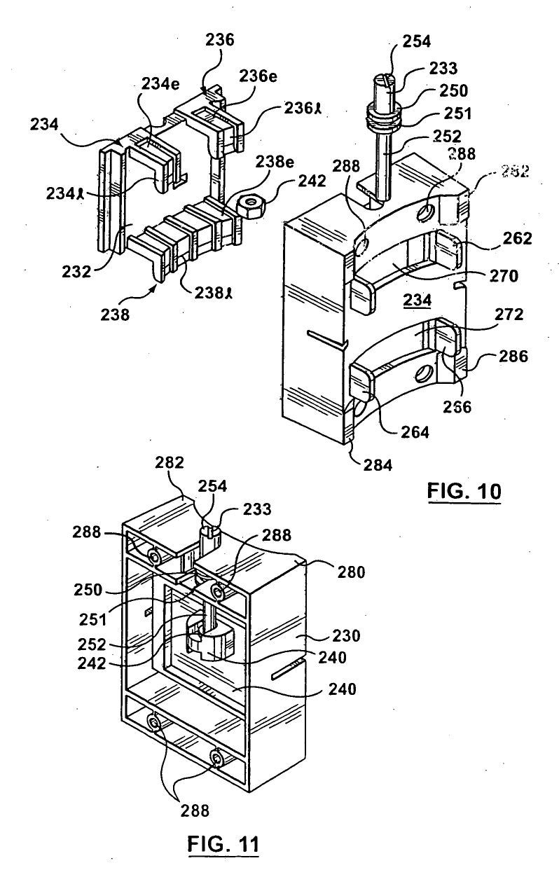

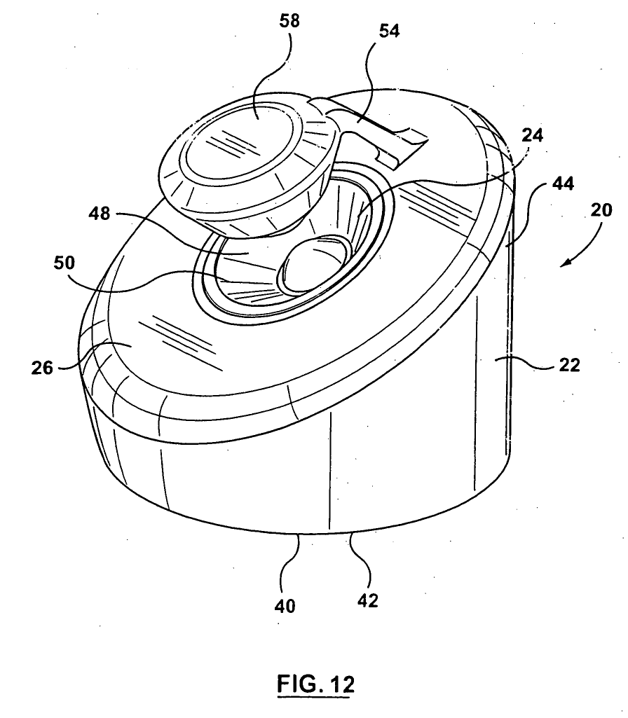

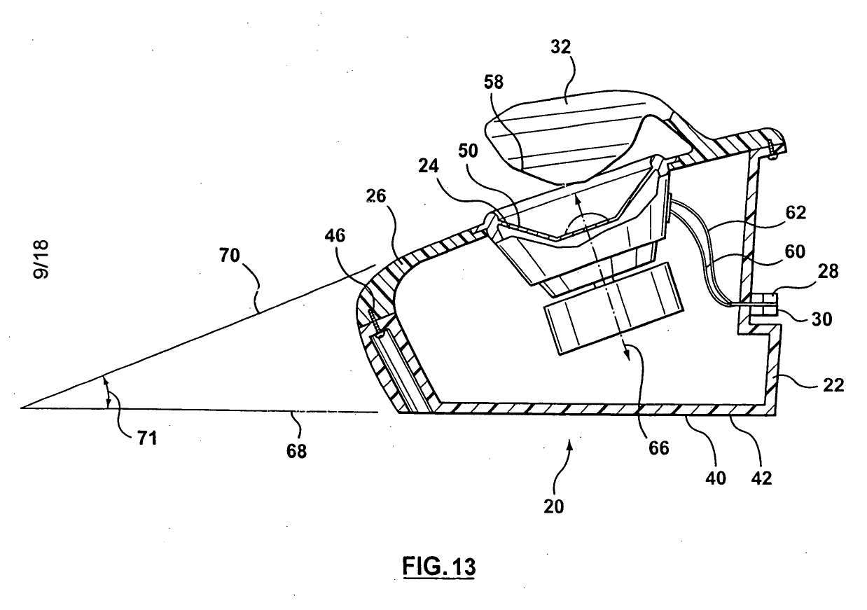

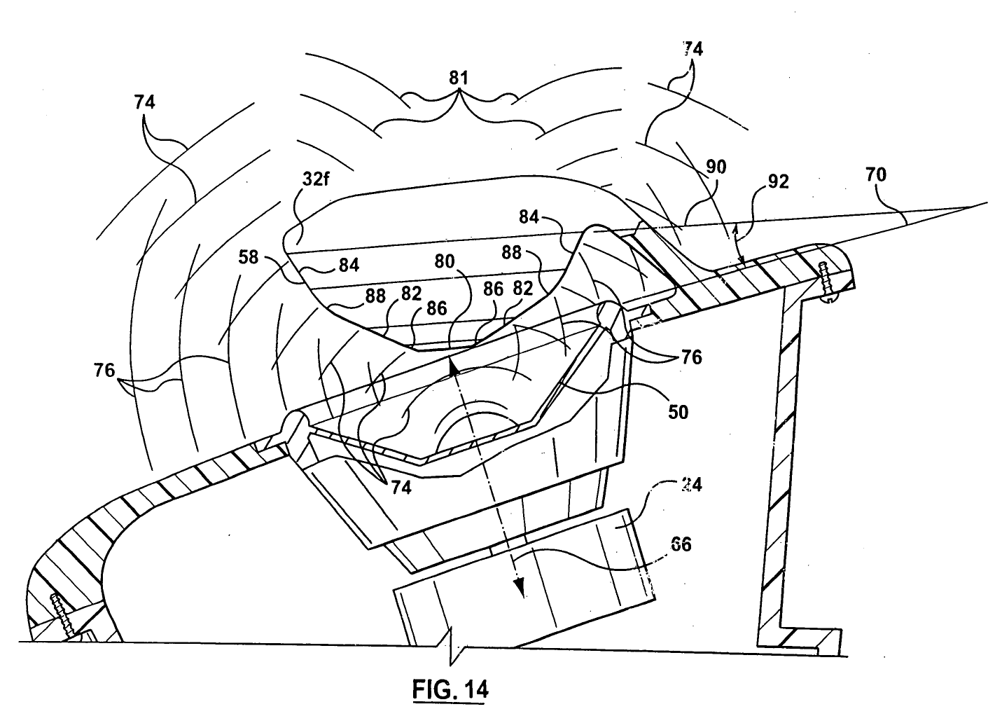

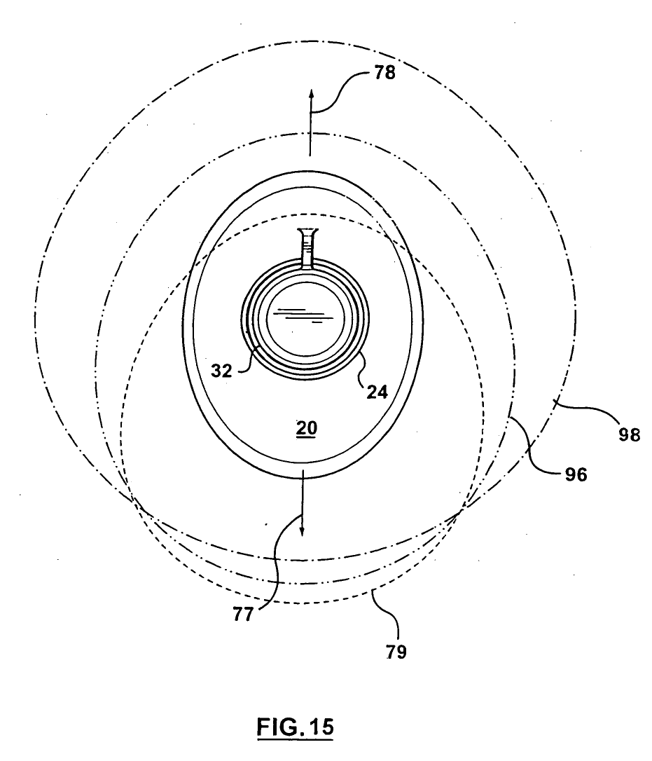

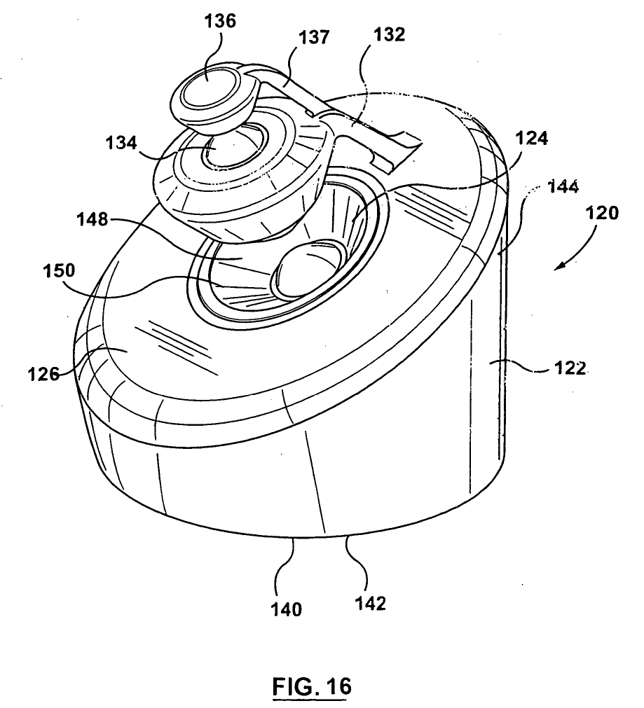

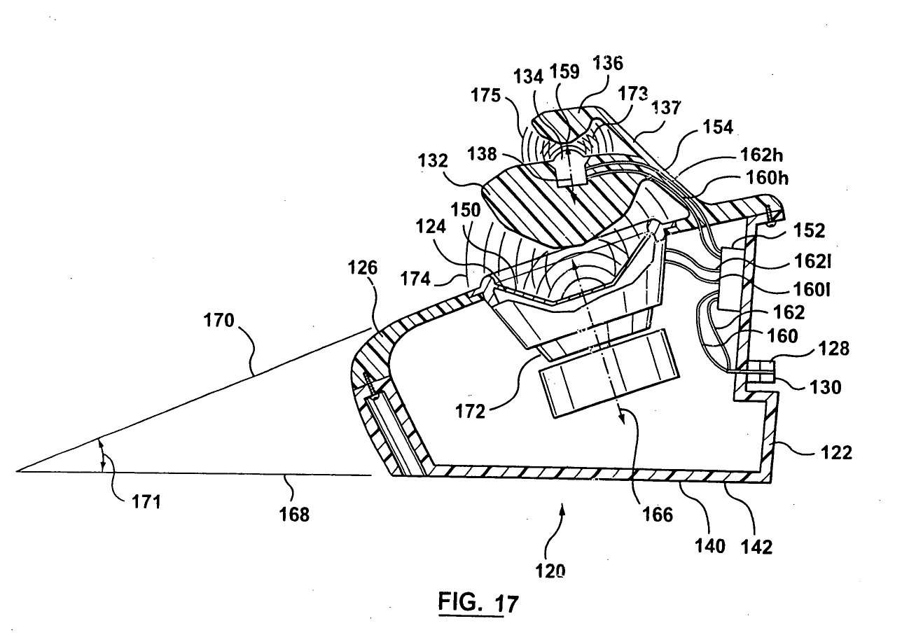

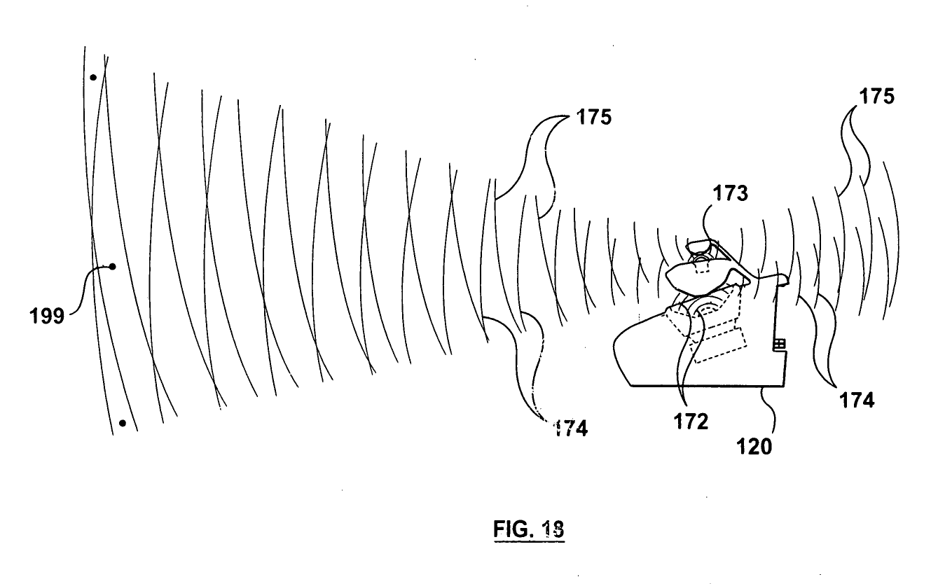

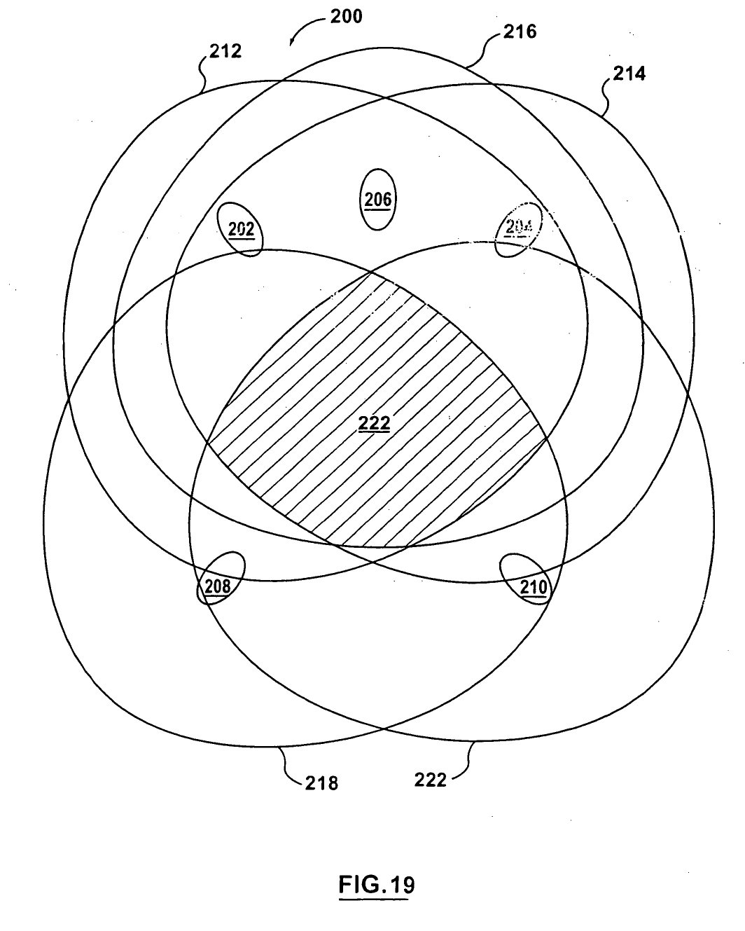

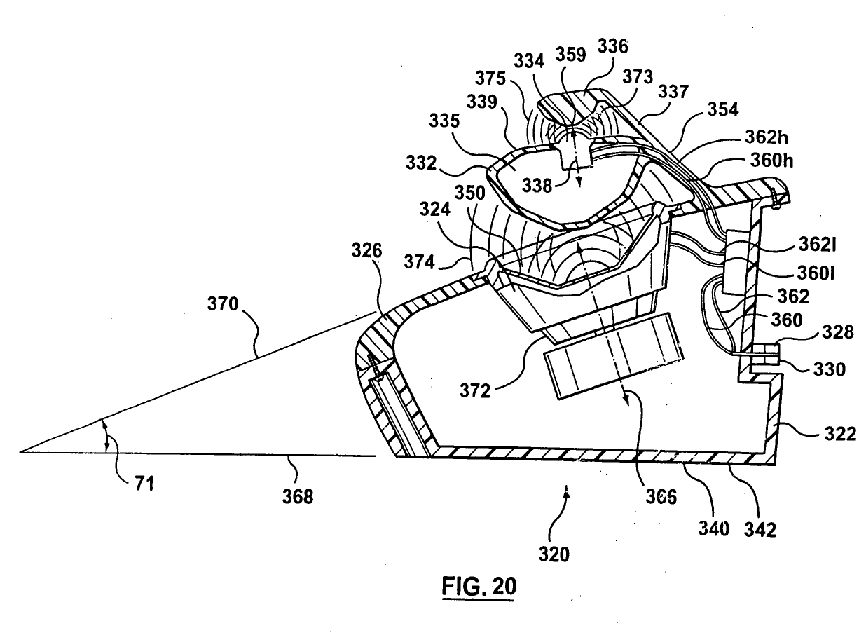

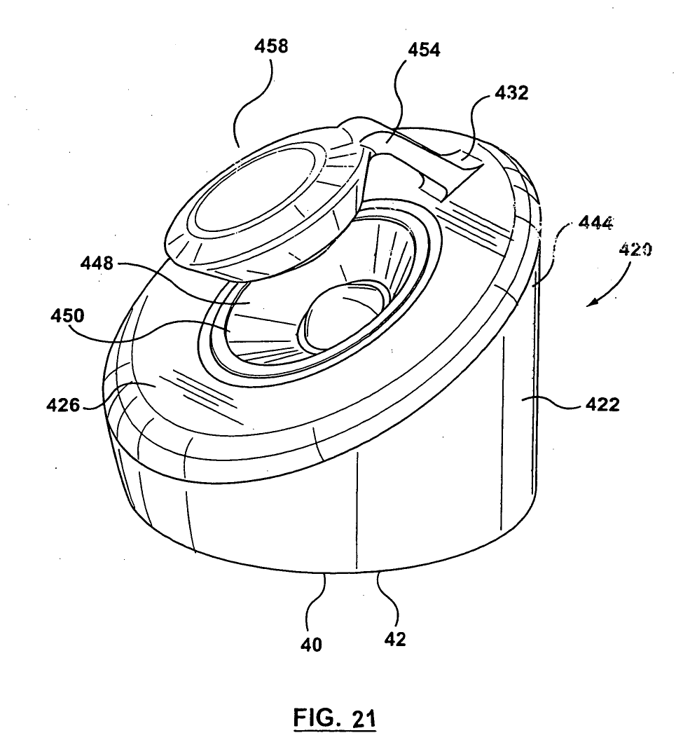

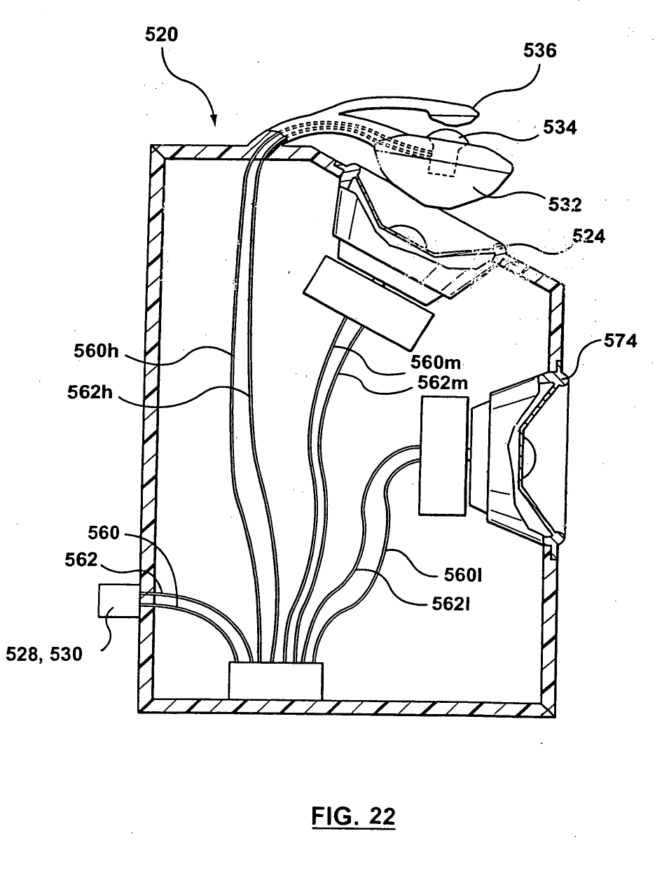

Reference is next made to FIGS. 8, 9, 10 and 11. FIGS. 8 and 9 shows mounting bracket 120 in an unlocked state and a locked state, respectively. Mounting bracket 120 has a mounting plate 230, a locking plate 232 and a locking screw 233.

Locking plate 232 has a several locking arms 234, 236 and 238 extending from its front side 240. Locking arm 234 has an “L” shaped cross section formed by an extension member 234e and a locking member 2341. Similarly, locking arm 236 has an extension member 236e and a locking member 2361 and locking arm 238 has an extension member 238e and a locking member 2381.

Locking screw 233 has a pair of flanges 250, 251 and a threaded shaft 252. The head of locking screw 233 has a slot 254 that may be engaged using a corresponding slot screwdriver to turn locking screw 233. Alternatively, locking screw could have a head designed for any other type of turning tool, such as a square drive screwdriver, a Philips (cross) screwdriver, a four or six-sided nut, alien key. Locking screw may be configured to require a special or proprietary tool to turn it, in order to prevent unauthorized persons from using locking screw 233 to remove loudspeaker 100 from mounting bracket.

Locking plate 232 has a mount 240 in which a nut 242 may be positioned. Nut 242 is inserted into locking plate 232 through an aperture 243 in locking plate 232. Locking screw 233 is screwed into nut 242.

The front surface 234 of mounting plate 230 is shaped to correspond to the shape of the back 129 of loudspeaker 100. Mounting plate 230 has four support arms 260, 262, 264 and 266. An aperture 270 extends between support arms 260 and 262 and an aperture 272 extends between support arms 264 and 266. Mounting plate 230 also has four positioning shoulders 280, 282, 284 and 286 formed at its corners. Screw holes 288 may be used to fasten mounting plate 230 to an external support.

Reference is additionally made to FIGS. 2, 3 and 4, which illustrate loudspeaker 100 positioned on mounting bracket 120. Support arms 260, 262, 264 and 266 and positioning shoulders 280, 282, 284 and 286 are positioned on mounting plate 230 so that when loudspeaker 100 is positioned on mounting plate 230: arms 260 and 262 are positioned in mounting channel 220; arms 264 and 266 are positioned in mounting channel 222; shoulders 280 and 282 are positioned in different detents 228 in row 224; and shoulders 284 and 286 are positioned in different detents 228 in row 226.

Locking plate 232 may be slideably positioned in a recess 268 with locking arms 234 and 236 extending through an aperture 270 and with locking arm 238 extending through aperture 272. Prior to placing locking plate 232 in mounting plate 230, locking screw 233 is rotated so that flanges 250, 251 are aligned with shoulder 274 and locking arms 234 and 236 are aligned with aperture 270 and locking arm 238 is aligned with aperture 272. Mounting bracket 120 is then assembled in an unlocked position as shown in FIG. 8, so that locking arms 234 and 236 are aligned with support arms 260 and 262 and locking arm 238 are aligned with support arms 264 and 266. Flanges 250, 251 engage shoulder 274 to prevent locking screw 233 from moving axially relative to mounting plate 230 when mounting screw 233 is rotated. When locking screw 233 may be rotated to move locking plate between the unlocked position shown in FIG. 8 and the locked position shown in FIG. 9.

Loudspeaker 100 may be mounted on mounting bracket 120 as follows. Mounting bracket is assembled with locking plate in its unlocked position as shown in FIG. 8. Loudspeaker 100 and mounting bracket 120 are positioned so that support arms 260 and 262 and locking arms 234 and 236 are positioned in insertion channel 220i; arms 264 and 266 and locking arm 238 are positioned in insertion channel 222i; shoulders 280 and 282 are positioned in different detents 228 in row 224; and shoulders 284 and 286 are positioned in different detents 228 in row 226.

Locking screw 233 is rotated to moving locking arms into the locked position illustrated in FIG. 9, moving locking members 2341 and 2361 into locking channel 2201 and moving locking member 2381 into locking channel 2221. Support arms 260 and 262 engage support surface 220s and support arms 264 and 266 engage support surface 222s. The L-shaped locking arms of mounting bracket 120 engage the L-shaped mounting channels 222 of loudspeaker 100, preventing loudspeaker 100 from being removed from mounting bracket 120 (without moving the locking arms). The positioning shoulder on mounting bracket 120 engage detents 228 on loudspeaker 100, preventing the support arms of mounting bracket 120 from sliding in the mounting channels 222. Loudspeaker 100 is effectively locked into a fixed position on mounting bracket 120.

Mounting bracket 120 allows loudspeaker 100 to be installed with a great deal of control over its direction. Mounting bracket 120 is first mounted an external support using screws positioned in screw holes 280. Loudspeaker 100 is then be positioned on mounting bracket 120 and rotated to a desired position. Locking screw 133 is then used to lock loudspeaker 100 on mounting bracket 120 in the desired position.

Mounting bracket 120 may be installed on an external support at any angle, allowing loudspeaker 120 to be installed with its top and bottom directed along a vertical line, a horizontal line or at any other angle.

In other embodiments on the present invention, any number of mounting channels 222 may be formed on enclosure 102 of the loudspeaker and the mounting bracket 120 may be provided with corresponding support arms and locking arms. Similarly, the number and arrangement of detents 228 may be changed and mounting bracket 120 will be provided with shoulders in a complementary position.

The present invention has been described by way of example only. The embodiments described may be varied without departing from the spirit and scope of the invention, which is limited only by the appended claims.

### Appendix A

### FIELD OF THE INVENTION

This invention relates to audio loudspeakers.

### BACKGROUND OF THE INVENTION

Omni-directional loudspeakers, which transmit sound in all directions are well-known. Typically, such loudspeakers have an axis along which at least one driver is mounted such that the driver's cone moves in an axial direction. Typically the axial direction is normal to the floor or ground of the area in which the loudspeaker is used. The driver generates sound waves which propagate either upwards away from or downwards towards the floor or ground. A sound reflector is positioned co-axially with the driver to reflect the sound waves to produce reflected waves which propagate away from the loudspeaker with equal strength in all directions. Such omni-directional speakers desirably provide a wide sound field which allows a person positioned in any direction around the loudspeaker to hear wide bandwidth sound produced by the loudspeaker.

Modern sound systems, including so-called home theatre systems, often incorporate 5 or more loudspeakers which are positioned at various locations within a listening room. The loudspeakers are preferably configured and positioned to provide a balanced sound field in a listening area. To increase the size of the listening area in which a relatively flat frequency response is achieved, it is desirable to use loudspeakers with a relatively wide sound field. To enhance the balance of the sound field at the listening position, it is desirable to control the shape of the sound field produced by any particular loudspeaker. To achieve a wide sound field from a loudspeaker, it is desirable to attain a wide dispersion pattern across a wide portion of the audible frequency range.

Accordingly, it is desirable to provide a loudspeaker that allows the wide sound field characteristics of an omni-directional loudspeaker to be shaped.

### SUMMARY OF THE INVENTION

An object of an aspect of the present invention is to provide an improved loudspeaker.

In accordance with this aspect of the present invention there is provided a loudspeaker comprising: (a) a base for supporting the loudspeaker relative to an external support, wherein the external support provides support in an external support plane; (b) a driver mounted to the base, the driver being movable parallel to a direction of movement to produce sound waves; and, (c) a reflector mounted in front of a diaphragm of the driver for reflecting sound waves from the driver. The direction of movement is at a non-zero acute angle to the external support plane.

An object of a second aspect of the present invention is to provide an improved loudspeaker.

In accordance with this second aspect of the present invention there is provided a loudspeaker comprising: (a) a base for supporting the loudspeaker relative to an external support, wherein the external support provides support in an external support plane, the base having an input terminal for receiving an audio signal and a cross-over connected to the input terminal for dividing the audio signal into a plurality of component signals; (b) a first driver mounted to the base and linked to the cross-over to receive a first component signal in the plurality of signals, the first driver being drivable by the first component signal to move parallel to a first direction of movement to produce sound waves, wherein the first direction of movement is at a first non-zero acute angle to an external support plane; (c) a first reflector mounted in front of a first diaphragm of the first driver for reflecting sound waves from the first driver; and, (d) at least one of a second driver for producing higher frequency sound waves than the sound waves produced by the first driver and a third driver for producing lower frequency sound waves than the sound waves produced by the first driver, the at least one of the second driver and the third driver being mounted to the base and linked to the cross-over to receive at least one component signal in the plurality of component signals from the crossover.

An object of a third aspect of the present invention is to provide an improved loudspeaker.

In accordance with this third aspect of the present invention there is provided a method of directing sound waves from a driver of a loudspeaker. The method comprises: (a) providing an audio signal to the driver, the driver being movable parallel to a direction of movement to produce sound waves based on the audio signal; (b) orienting the driver such that the direction of movement is at a selected angle of inclination relative to a horizontal plane, the selected angle of inclination being a non-zero acute angle; and, (c) reflecting sound waves from the driver.

### BRIEF DESCRIPTION OF THE DRAWINGS

A preferred embodiment of the present invention will now be described in detail with reference to the drawings, in which:

FIG. 12 is a perspective drawing of a loudspeaker according to a first embodiment of the present invention;

FIG. 13 is a cross-sectional side view of the loudspeaker of FIG. 12;

FIG. 14 is a detailed cross-sectional view of a sound reflector and a driver of the loudspeaker of FIG. 12;

FIG. 15 is a top view of the loudspeaker of FIG. 12;

FIG. 16 is a perspective drawing of a loudspeaker according to a second embodiment of the present invention;

FIG. 17 is a cross-sectional side view of the loudspeaker of FIG. 16;

FIG. 18 is a side view of the loudspeaker of FIG. 16 illustrating a sound field;

FIG. 19 illustrates the use of a multiple speakers according to the present invention;

FIG. 20 is a cross-sectional side view of a loudspeaker according to a third embodiment of the present invention;

FIG. 21 is a perspective view of a loudspeaker according to a fourth embodiment of the present invention; and

FIG. 22 is a cross-sectional side view of a loudspeaker according to a fifth embodiment of the present invention.

### DETAILED DESCRIPTION OF THE INVENTION

Human hearing is at its most sensitive to sound within a fairly narrow region between 2 kHz and 5 kHz. This is also the region where our brains perform much of the processing needed to localize or determine the position or origin of sound.

In audio systems, multiple loudspeakers are used to recreate a three-dimensional recorded event. That is, a three-dimensional effect is created through the position, intensity and time delay between the two or more channels. Our brains are able to recreate a sense of space and size because of this, as well as a sense of the reflections that occur within a typical room. For example, listening to a symphony orchestra in a very good concert hall, one hears sound that has a very high proportion of reflected information. Typically, 70% of the audio information will be reflected, and only 30% will be direct sound from the performance on stage.

If we listen to a typical speaker with drivers on the vertical plane, much of the sound, particularly at high frequencies, will be directed right at the listener and the reflected content will be minimal. This lack of reflected information, compared to what happens in reality, would reduce the perceived size of the sound—the “soundstage”. However, because of the large amount of direct signal between 2 kHz to 5 kHz, a speaker with drivers on the vertical plane will produce tightly defined acoustic images. In the other extreme, in a prior art omni directional speaker with a reflector above a driver on the horizontal plane, the ratio of reflected information to direct information from the speaker will be very high. As a result, a large sense of space, such as in a concert hall, will be created in the brain. However, as very little direct signal reaches the listener, particularly in the 2 kHz to 5 kHz region, poorly defined images that do not mimic reality will be created in the brain.

Embodiments of the present invention permit the ratio of direct signal to reflected signal to be varied, particularly at frequencies between 2 kHz to 5 kHz, which is the upper operating range of a woofer. By doing so, the reflected information required to produce a large soundstage can be retained. At the same time, by also retaining a sufficient amount of direct signal, the image created by the sound can be focused to better duplicate the sound of a live performance.

Reference is first made to FIG. 12, which illustrates a loudspeaker 20 according to a first embodiment of the present invention. Loudspeaker 20 has a housing 22, a driver 24, a housing baffle 26, input terminals 28, 30 (FIG. 13) and a sound reflector 32.

Housing 22 has a base 40, which also defines the base 42 of loudspeaker 20. Baffle 26 is mounted on the top 44 of housing 22 using several screws 46 (FIG. 13). Alternatively, baffle 26 may be mounted to housing 22 using a friction mount, another type of fastener or any other method. Driver 24 is mounted in an opening 48 in baffle 26. Driver 24 is mounted such that its cone 50 faces out from the top of baffle 26. Sound reflector 32 is formed integrally with baffle 26 and is spaced apart from baffle 26 by support 54, which is also formed integrally with baffle 26. In another embodiment of the present invention, sound reflector 32 and support 54 may be formed separately from baffle 26 and may be assembled with baffle 26 using one or more fasteners and/or an adhesive.

Sound reflector 32 is positioned above driver 24 and has a sound reflecting surface 58 which faces the cone 50 of driver 24.

Terminals 28, 30 are mounted on a rear side of housing 22. Terminals 28, 30 may be any type of mounting terminals suitable for attaching audio cables (not shown). Terminals 28, 30 are coupled to driver 24 by wires 60, 62 (FIG. 13).

Referring next to FIG. 13, the base 42 of loudspeaker 20 generally defines a base plane 68, which in operation rests on external support plane, provided by, for example, a floor or a bookshelf. The top edge of cone 50 defines a driver plane 70. Driver plane 70 is at an angle 71 to base plane 68.

In use, loudspeaker 20 may be positioned so that base plane 68 is substantially parallel to the floor or ground (not shown) in the area where loudspeaker 20 is used. As a result, driver plane 70 will typically not be parallel to the floor or ground. Alternatively, loudspeaker 20 may be suspended from a ceiling so that its base is parallel to the floor or ground, or it may be mounted with its base or back against a wall.

In use, loudspeaker 20 receives an audio signal at terminals 28, 30 from a signal source (not shown) in known manner. The signal source may be an audio receiver or amplifier. A skilled person will understand the operation and connection of an appropriate audio source and this is not further described here.

Reference is next made to FIG. 14, which is an enlarged view of driver 24 and sound reflector 32. Driver 24 receives the audio signal through wires 60, 62 (FIG. 13) and causes its cone 50 to move in an axial direction 66, which will typically be normal to driver plane 70. As cone 50 moves, it creates sound waves 74. Sound waves 74 have a range of frequency components with the specific range depending on the selection of driver 24. Higher frequency components, and particularly those with a wavelength shorter than the diameter of cone 50, are propagated in a direction generally normal to driver plane 70, in the direction of reflecting surface 58. As sound waves 74 strike reflecting surface 58, they are reflected outwardly from loudspeaker 20 as sound waves 76. Although sound waves 76 are shown propagating from loudspeaker towards the front and rear of loudspeaker 20, sound waves 76 will actually propagate away from loudspeaker 20 in all directions.

Reference is additionally made to FIG. 15. Reflector 32 is positioned above driver 24 such that sound waves 74 are reflected as sound waves 76 unequally. Relatively large portions of sound waves 76 are reflected in direction 77 from the front of loudspeaker 20. This means that a relatively large portion of the sound energy produced by driver 24 is directed outward from the loudspeaker 20 in direction 77.

Progressively less of sound waves 76 (and progressively less of the sound energy produced by sound energy produced by loudspeaker 20) are reflected in each direction at progressively larger angles from the front of loudspeaker 20. The smallest portions of sound waves 76 are reflected in direction 78 towards the rear of loudspeaker 20. Curve 79 illustrates the relative strength of the sound waves 76 reflected in all directions away from loudspeaker 20.

Reference is again made to FIG. 14. The relative amplitude of sound waves 76 propagated away from loudspeaker 20 in any direction depends on the shape and size of reflector 32, the position of reflector 32 with respect to driver 24 and the size and shape of driver 24. The reflecting surface 58 of sound reflector 32 has a compound surface with three flat sections 80, 82 and 84 separated by curved sections 86 and 88. Curved section 86 has a smaller radius of curvature than curved section 88.

The particular size and shape of reflecting surface 58 in any particular embodiment of a loudspeaker 20 according to the present invention will depend on the frequency response of the driver 24 and on the frequency response desired for the loudspeaker 20. Driver 24 of this exemplary loudspeaker 20 is a full range loudspeaker chosen to cover a large portion of the audible frequency spectrum. The shape of reflection surface 58 has been found to provide a relatively flat frequency response for loudspeaker 20, when used with such a loudspeaker. If a different frequency response or dispersion pattern is desired for loudspeaker 20, a differently shaped reflection surface may be used. For example, a parabolic, elliptical, hyperbolic or circular reflection surface may be used in alternative embodiments.

A driver 24 of any shape or size may be used with the present invention. If a larger driver 24 is used, a larger proportion of the generated sound waves will be directional. The size of sound reflector 74, 76 may need to be increased, if it is desired that the reflector 32 effectively redirect the large range of directional frequency components.

Reference is made to FIG. 15. The degree to which reflector 32 is effective in reflecting sound waves 74 also depends on the frequency of the sound waves 74. It is well known that low frequency audio waves are less directional than higher frequency audio waves. This means that a low frequency sound diverges more widely and propagates in virtually all directions (in three dimensions) away from its source (typically a loudspeaker). A high frequency sound on the other hand is less divergent and propagates in a comparatively narrow or focused direction compared to the low frequency sound. In the absence of sound reflector 32, low frequency sounds produced by driver 24 would propagate widely in all directions away from loudspeaker 20. However, high frequency sounds would travel upwards along line 66 (FIG. 14) and would diverge much more narrowly.

High frequency sound waves are more easily reflected by obstacles in their paths, particularly when the obstacle is larger than the wavelength of the sound waves. In contrast, lower frequency sound waves are affected to a lesser degree by obstacles in their path. This means that higher frequency components of sound waves 74 (FIG. 14) will be reflected by sound reflector 32 more than lower frequency components. Sound reflector 32 is sized so that its diameter 90 is larger than the wavelength of frequency components that sound reflector 32 is intended to reflect.

As noted above, driver 24 is selected to generate sound waves 74 with a broad range of frequency components. Curve 79 illustrates the shape of the sound field produced by loudspeaker 20 for relatively high audio frequencies. Curve 96 illustrates the shape of the sound field produced by loudspeaker 20 for mid-range audio frequencies. Curve 98 illustrates the shape of the sound field produced by loudspeaker 20 for relatively low audio frequencies. Curves 79, 96 and 98 are merely illustrative, are not to scale and do not define boundaries of the sound field at each frequency range. They are intended to illustrate the general shape of wave propagation in each frequency range. Curves 79, 96 and 98 illustrate that the total sound field produced by loudspeaker 20 will have more directional higher frequency components and less directional low frequency components. The sound field produced by loudspeaker 20 will radiate away from loudspeaker 20 in three dimensions. The vertical shape of the sound field at frequency range is similar to its horizontal dimension. Thus, curves 79, 96 and 98 illustrate the cross-section of the sound field in each corresponding frequency range.

The shape of reflecting surface 58 has been found to give a relatively flat frequency response for loudspeaker 20 across a wide frequency range, when measured from a horizontal position at about the height of loudspeaker 20. Loudspeaker 20 provides a large three-dimensional listening area at its front side and makes efficient use of the sound energy generated by driver 24 in doing so.

In this exemplary loudspeaker 20, the angle 71 between base plane 68 and driver plane 70 is 25 degrees. In other embodiments of the present invention, this angle is 30 degrees. This angle is chosen to provide a flat driver frequency response along axis 66 (FIG. 14). In other embodiments of the present invention, this angle may be between 5 and 85 degrees, between 10 degrees and 80 degrees, or between 20 and 35 degrees.

A sound reflector plane 90 may be defined for sound reflector 32 across the top of reflecting surface 58. The angle 92 between sound reflector plane 33 and driver plane 70 is chosen based on the sound dispersion pattern that is desired to be produced by loudspeaker 20. The desirable sound dispersion pattern will depend on the application of the loudspeaker 20. For example, depending on the room (or type of room) in which the loudspeaker 20 is expected to be used, different sound reflections will occur at the room's boundaries (i.e. the walls defining the room). Typically, loudspeaker 20 will be placed with its rear close to the wall or the back of a bookshelf. By angling sound reflector 32 so that its front side 32f is angled downwards, as in the exemplary loudspeaker 20, the sound waves directed from the front of loudspeaker 20 will be concentrated towards a listener in front of the loudspeaker 20 at generally the same height as the loudspeaker 20. At the same time, the sound waves reflected from the back of the loudspeaker 20 will have a slight upwards direction and will bounce off the wall or bookshelf and be reflected frontwards and upwards at a generally higher height than the sound waves reflected from the front of loudspeaker 20. This contributes to a spacious sound field. Angle 92 affects the vertical response characteristics of a loudspeaker made according to the present invention. A skilled person will be capable of selecting an appropriate angle to provide a desired sound filed characteristic.

Sound reflector 32 operates to shape both the horizontal and vertical shape of the sound field produced by loudspeaker 20. The shape and the angle of sound reflector 32 relative to driver plane 70 have been described above. As sound waves 74 produced by driver 24 encounter sound reflector 32, some of them will actually wrap around sound reflector 32 and form diffracted sound waves 81 (FIGS. 13 and 14) above sound reflector 32. Higher frequency components of sound waves 74 that have a wavelength smaller than the diameter of sound reflector 32 will be both diffracted and reflected by sound reflector 32 as sound waves 81 and as sound waves 76. The proportion of the sound waves 74 that will be diffracted increases as the size of the sound reflector 32 is reduced. Sound reflector 32 may be sized to provide a desired sound field may be produced in both the horizontal and vertical directions in the listening area.

As noted above, loudspeaker 20 is provided with a driver 24 selected to produce sound with a wide frequency range in response to an audio signal. It may be desirable to generate different audio frequency ranges (which may overlap) with different drivers.

Reference is next made to FIGS. 16 and 17, which illustrate a loudspeaker 120 according to a second embodiment of the present invention. Components of loudspeaker 120 corresponding to components of loudspeaker 20 are identified with similar reference numerals increased by 100. Loudspeaker 120 has a housing 122, a driver 124, a housing baffle 126, input terminals 128, 130, a sound reflector 132, which are structured and operate in generally the same manner as the corresponding components of loudspeaker 20 (FIG. 12). In addition, loudspeaker 120 has a second driver 134, a second sound reflector 136 and a cross-over 152.

Driver 134 is mounted in the top side of sound reflector 132 and has an axis 138. Sound reflector 136 has a support 137 which extends from support 154 (or from the top of sound reflector 132). Sound reflector is positioned generally above driver 134.

Driver 134 is a high frequency driver, which is selected to produce sound waves at a higher frequency range than driver 124, typically with some overlap between the two frequency ranges. For example, in loudspeaker 120, driver 124 may be selected to produce sound between 50 Hz and 2 kHz and driver 134 may be selected to produce sound between 1 kHz and 18 kHz. (Typically the high end of the frequency range of driver 124 will be lower than that of driver 24 in loudspeaker 20, since loudspeaker 20 does not have a high frequency driver.) In another embodiment of the present invention, drivers 124 and 134 may be selected to have any suitable frequency range.

Cross-over 152 is mounted inside housing 122 and is coupled to terminals 128, 130 by wires 160, 162. Driver 124 coupled to cross-over 152 by wires 1601, 1621. Driver 134 is coupled to cross-over 152 by wires 160h and 162h. Cross-over 152 receives an audio signal from terminals 128, 130 and divides it into a low frequency audio signal and a high frequency audio signal in known manner. The low and high frequency audio signals have overlapping frequency ranges.

Driver 124 receives the low frequency audio signal from cross-over 152 and in response produces audio waves 172 in the same manner as driver 124 produces audio waves 72 (FIG. 15). Audio waves 172 are reflected by reflector 132 as sound waves 174.

Driver 134 receives the high frequency audio signal from cross-over 152 and in response produces audio waves 173. Reflector 136 is positioned such that at least some of audio waves 173 are incident on it. A reflecting surface 159 of reflector 136 reflects audio waves 173 outward from loudspeaker 120 as sound waves 175. A relatively large portion of sound waves 175 is directed from the front of loudspeaker 120. Progressively less of sounds waves 175 are in each direction at progressively larger angles from the front of loudspeaker 120.

The use of separate drivers 124 and 134 in loudspeaker 120 has several advantages over the single driver design of loudspeaker 20. First, the use of two drivers 124 and 134 allows drivers to be selected that provide a better sound quality within their selected frequency ranges. Second, the use of independent reflectors 132, 136 for the separate frequency ranges allows the sound field for each frequency range to be shaped more precisely, allowing the overall sound field of loudspeaker 120 to be shaped more closely to a desired shaping. The driver 134 is located further from the front of the loudspeaker 120 than the driver 124. Similarly, the reflector 136 is further from the front of the loudspeaker 120 than the reflector 132. As a result, the audio waves 172 from the driver 124 and reflector 132 have less distance to traverse to a listener than the audio waves 173 from the driver 134 and reflector 136. This is desirable as the audio waves 173 from the high frequency audio signal would otherwise reach a listener slightly before the audio waves 172 from the low frequency audio signal.

Reference is next made to FIG. 18. Sound waves 174 and 175 are illustrated in cross-section propagating from the front and back of loudspeaker 120. Sound waves 174 and 175 collectively provide a sound field that covers the frequency ranges of both drivers 124 and 134. A listener situated at point 199a will hear the combined full sound field. Like loudspeaker 20, loudspeaker 120 produces a three-dimensional sound field. A speaker situated at points 199b and 199c which are respectively above and below the height of speaker 120 will also hear the combined full sound field. A skilled person will be capable of selecting the angles of driver 124 and 136 and their reflectors 132, 136 to provide the combined sound field at the height required for any particular embodiment of the present invention.

Reference is next made to FIG. 19. Speakers 20 and 120 are suitable for use in multiple channel sound systems. Modern home theatre systems commonly include five or more speakers. A typical home theatre loudspeaker system 200 may include a front left loudspeaker 202, a front right loudspeaker 204, a center loudspeaker 206, a rear left loudspeaker 208 and rear right loudspeaker 210. The sound field of each of these speakers in the 2-5 kHz band is symbolically illustrated in FIG. 20 by curves 212 (front left loudspeaker 202), 214 (front right loudspeaker 204), 216 (center loudspeaker 206), 218 (rear left loudspeaker 208) and 220 (rear right loudspeaker 210). Each of these curves illustrate the region in which the associated loudspeaker may be effectively heard, in the shown layout. The five curves 212 to 220 overlap to provide a listening area 222. A listener situated in the listening area 222 will be able to hear all five speakers 202 to 210 and will enjoy a typical “surround sound” audio presentation from all five speakers, under the control of a sound signal source (not shown).

As mentioned earlier, low frequency sounds are relatively non-directional. In addition, a substantial amount of power is often required to generate such low frequency sounds. The five loudspeaker system of FIG. 19 may be combined in known manner with a low frequency loudspeaker or “sub-woofer” in a “5.1” loudspeaker system that provides a sound field with a wide frequency range. For example, the low frequency loudspeaker may have a frequency range of 20 Hz to 80 Hz. The drivers 124 of speakers 202 to 210 may have a frequency range of 60 Hz to 2 kHz and the driver 134 of speakers 202 to 210 may have a frequency range of 1 kHz to 18 kHz. These frequency ranges are only exemplary and a skilled person will be capable of selecting drivers with frequency ranges that suit a particular application of the present invention.

Reference is next made to FIG. 20, which illustrates a loudspeaker 320 according to a third embodiment of present invention. Loudspeaker 320 has a structure similar to loudspeaker 120 and corresponding components are identified by similar reference numerals increased by 200. High frequency driver 334 operates in a manner similar to high frequency driver 134. However, sound reflector 332 has been hollowed out to provide a sealed rear chamber 335 for high frequency driver 334. High frequency driver 334 has a hole 337 to release air pressure caused by movement of its cone 351. This volume of air contained within reflector 332 reduces the fundamental resonance of driver 334, thereby reducing distortion and improving power handling at the bottom of its frequency range and smoothing out its frequency response.

Reference is next made to FIG. 21, which shows a loudspeaker 420 according to a fourth embodiment of the present invention. The speakers described above all incorporate circular driver (i.e. drivers 24 and 134). The present invention may be used with a driver having an elliptical or other shape. Loudspeaker 420 is similar to loudspeaker 20. Corresponding components of loudspeaker 420 are identified by similar reference numerals increased by 400. Driver 424 has an elliptical shape and sound reflector 432 has a corresponding elliptical shape.

In other embodiments of the present invention, the driver (or drivers) may have any shape. For example, they may be conical, flat or dome shaped.

Loudspeakers 120 and 320 have two drivers and two corresponding reflectors. Other loudspeakers according to the present invention may have three or more drivers and corresponding reflectors. The three or more loudspeakers may have different and possibly overlapping frequency ranges. The drivers of such loudspeakers may be selected to provide a wider combined frequency response or a better quality sound reproduction or both.

Reference is next made to FIG. 22, which illustrates a fifth embodiment of a loudspeaker 520 according to the present invention. Loudspeaker 520 has three drivers 524, 534 and 574. Driver 524 has a corresponding reflector 532 and driver 534 has a corresponding reflector 536. Drivers 524, 534 and reflectors 532, 536 operate in the same manner as drivers 124, 134 and reflectors 132, 136 of loudspeaker 120 (FIG. 17). Loudspeaker 520 has input terminals 528 and 530 which are coupled to a three way cross-over 552. Cross-over 552 divides an audio signal (not shown) received at terminal 528, 530 into low, mid-range and high frequency components. The high frequency components are provided to driver 534 through wires 560h, 562h. The mid-range frequency components are provided to driver 524 through wires 560m, 562m. The low frequency components are provided to driver 574 through wires 5601, 5621.

Driver 574 is selected to have a low frequency operational range and along with crossover 552 reproduces audio in response to the low frequency components of the audio signal. Since the low frequency audio output of driver 574 will be essentially omni-directional, driver 574 does not require a sound reflector.

Loudspeaker 520 is capable of producing sounds with a very wide frequency range, depending on the selection of drivers 524, 534 and 574, and with wide listening area.

Other variations and modifications of the invention are possible. For example, while the foregoing has referred to drives having cones, those of skill in the art will appreciate that diaphragms of other shapes may be substituted. All such modifications or variations are believed to be within the sphere and scope of this invention.

We claim:

1. A loudspeaker enclosure comprising:
(a) a passive radiator aperture and an active driver aperture;
(b) a passive diaphragm positioned essentially centrally within the passive radiator aperture; and
(c) a passive diaphragm suspension extending between the diaphragm and the speaker enclosure, the suspension holding the passive diaphragm in place and allowing the diaphragm to move linearly in a direction substantially normal to the surface of the diaphragm.

2. The loudspeaker enclosure of claim 1 further comprising a secondary passive suspension mounted to the passive diaphragm.

3. The loudspeaker enclosure of claim 1 wherein an active driver has been selected for installation in the active driver aperture, and wherein the passive diaphragm is tuned to a frequency below the low frequency cutoff frequency of the active driver.

4. A passive radiator mounted in a loudspeaker enclosure comprising:
(a) a passive diaphragm mounted essentially centrally in a passive radiator aperture formed in the enclosure;
(b) a passive diaphragm suspension for mounting the passive diaphragm to the enclosure and for permitting the passive diaphragm to move essentially linearly.

5. A loudspeaker having a passive radiator mounted in a passive radiator aperture formed in a loudspeaker enclosure, the process of forming the passive radiator formed comprising:
(a) assembling an injection mold with a first cavity and a second cavity;
(b) injecting resin into the first cavity to form a diaphragm of the passive radiator;
(c) injecting resin into the second cavity to form the enclosure;
(d) adjusting the mold to provide a third cavity that is continuous with the first and third cavities; and
(e) co-molding a suspension between the diaphragm and the enclosure.

6. The loudspeaker of claim 5 wherein the first cavity is positioned in the mold centrally in a passive radiator aperture defined by the second cavity.

7. The loudspeaker of claim 5 wherein the mold has two plates and an insert and wherein, in step (d), the third cavity is provided by separating the two plates, removing the insert and re-assembling the two plates.

8. The loudspeaker of claim 5 wherein the mold has three plates and wherein step (a) is performed by assembling the first and second plates together and step (d) is performed by assembling the first and third plates together.

9. The loudspeaker of claim 5 wherein step (d) is performed by removing blocking elements that separate the third cavity from the first and second cavities.

10. The loudspeaker of claim 5 wherein step (e) is performed before the passive diaphragm and enclosure have fully solidified.

11. The loudspeaker of claim 5 wherein a molecular bond is formed between the passive suspension and the enclosure and between the passive suspension and the passive diaphragm.

12. A method of manufacturing a loudspeaker comprising:
(a) forming an enclosure having a passive radiator aperture and an active driver aperture;
(b) forming a diaphragm within said passive radiator aperture;
(c) forming a diaphragm suspension to provide a seal between the speaker housing and the diaphragm, wherein the diaphragm permits the diaphragm to move linearly; and
(d) installing an active driver in the active radiator aperture with a seal between the active driver and the active driver aperture.

13. The method of claim 12 wherein steps (a) and (b) are performed simultaneously by injection molding the enclosure and the diaphragm.

14. The method of claim 13 wherein step (c) is performed before the speaker enclosure and the diaphragm have fully solidified.

15. The method of claim 13 wherein the first material is a plastic.

16. The method of claim 14 wherein the plastic is selected from the group consisting of ABS, polypropylene, polyethylene, acrylic, polystyrene, lexan, thermoset materials, thermoplastic rubbers.

17. A mounting bracket for a speaker having at least one mounting channel, said mounting channel having a support surface and having a locking channel, and the mounting channels extending along the surface of the speaker, wherein the mounting bracket comprises:
(a) a base having one or more support arms;
(b) a locking plate having one or more locking members movable between a locked and unlocked position,
wherein:
(i) when the locking members are in the unlocked position, the locking members are aligned with the support arms allow the locking members and support arms to engage the mounting channels; and
(ii) when the locking members are in the locked position, the support arms engage the support surface and the locking members extend into the locking channel.

18. The mounting bracket of claim 17 further comprising a positioning shoulder for engaging a positioning detent on the speaker, thereby preventing the support arms from moving along the mounting channel.
